(19) United States
(12) Patent Application Publication
(10) Pub. No.: US 2017/0263452 A1
(43) Pub. Date: Sep. 14, 2017

(54) METHOD FOR MANUFACTURING TWO-DIMENSIONAL MATERIAL STRUCTURE AND TWO-DIMENSIONAL MATERIAL DEVICE

(71) Applicant: INSTITUTE OF MICROELECTRONICS, CHINESE ACADEMY OF SCIENCES, Beijing (CN)

(72) Inventors: Yajuan SU, Beijing (CN); Kunpeng JIA, Beijing (CN); Chao ZHAO, Kessel-lo (BE); Jun ZHAN, Beijing (CN); Heshi CAO, Beijing (CN)

(21) Appl. No.: 15/261,068

(22) Filed: Sep. 9, 2016

(30) Foreign Application Priority Data
Mar. 11, 2016 (CN) 201610140337.0

(51) Int. Cl. H01L 21/02; H01L 21/4757; H01L 21/311

(52) U.S. Cl. CPC H01L 21/02527; H01L 21/02521; H01L 21/02568; H01L 21/02658; H01L 21/31111; H01L 21/47573; H01L 21/0259

(57) ABSTRACT

A method for manufacturing a two-dimensional material structure and a resultant two-dimensional material device. The method comprises steps of: forming a sacrificial FIN structure on a substrate; covering the sacrificial FIN structure with a dielectric; releasing the sacrificial FIN structure; forming a carrier FIN structure at a position for releasing the sacrificial FIN; and self-restrictedly growing two-dimensional material structure by taking the carrier FIN structure as a substrate. Utilizing the sacrificial FIN structure to implement self-restrictedly growing of the nanometer structure of the two-dimensional material results in a high precision, lower edge roughness, high yields and low process deviation as well as compatibility with the processing of CMOS large scale integrated circuits, making the method suitable for a large scale production of the two-dimensional material and related devices.

### CROSS-REFERENCE TO RELATED APPLICATION(S)

This application claims priority to Chinese Application No. 201610140337.1, filed on Mar. 11, 2016 and entitled “Method for manufacturing two-dimensional material structure and two-dimensional material device”, which is incorporated herein by reference in its entirety.

### FIELD OF THE INVENTION

The present disclosure relates to the semiconductor field, particularly to a method for manufacturing two-dimensional material structure and a two-dimensional material device, and more particularly to a method for manufacturing two-dimensional material structure and a two-dimensional material device which may control its topography and size.

### BACKGROUND

After an ultra-high speed of development of integrated circuits based on silicon process for about fifty years according to Moore's law, characteristic size has been decreased to 216/14 nanometers or smaller. When the technique for manufacturing integrated circuits is brought into a scale of nanometers, the process difficulty and process cost are greatly increased. The key technique has approached to its physical limitation which is dominated by quantum effect, and there is a great challenge for a durable development of the integrated circuit. In recent years, new material, new process and new device come forth to break through the bottleneck for the current CMOS technique in a nanometer scale.

A two-dimensional material is a novel material candidate. For example, graphene is a two-dimensional crystal with a thickness of one layer of atom which is peeled from graphite material and is constituted of carbon atoms. Graphene has very excellent and novel physical and chemical properties and is widely applied in various fields. It is focused in the field of integrated circuit that graphene functions as channel material to manufacture a transistor. Since graphene has ultra-high carrier mobility at a room temperature, a graphene transistor exhibits a better property than the conventional CMOS transistor. However, since a valence band of graphene is nicely filled in and a conduction band of graphene is fully empty, a Fermi-surface of graphene is exactly between the conduction band and the valence band. Since a bottom of the conduction band and the top of the valence band intersects at the point K, the Fermi-surface crosses over the point K, graphene can be deemed as a semiconductor material with a zero band gap. That is to say, graphene itself does not has a band gap, so a switch ratio of the graphene transistor is very low and can't be applied to applications requiring a high switch ratio of the device, such as logical circuit and so on. The primary technical problem of the graphene field effect transistor for the logical circuit is to adjust the band gap. Otherwise, it can't implement targets of high gain and low power consumption.

The current method for opening energy band of graphene mainly comprises the following: 1) rebuilding lattice of graphene; 2) applying a perpendicular electric field at a double-layer graphene; 3) introducing band gap by utilizing stress; 4) manufacturing graphene in a nanometer belt. The most popular and convenient method is to manufacture graphene in a nanometer belt to opening the energy band of graphene. However, there is provided a high requirement for the current process to manufacture graphene nanometer belt with sufficient band gap to open the energy bend.

In order to utilize the current process to manufacture graphene nanometer bent, respective research groups propose some distinctive methods which comprise electron beam exposure, chemical anisotropic etching, acoustic chemical method, tailoring of carbon nanometer tube, epitaxial growing of silicon carbide, organic synthesis, direction growth of metal template and so on. However, there is only some individual method which may be applied for large scale integration, and can't provide sufficiently narrow nanometer belt and sufficiently smooth edge. The methods as mentioned above may implement modulation of band gap in different levels and may enhance the gain, the deficiency of which is to need etching process, leads irregular edge of the material and even introduces defects, and decrease mobility of the material. Most of the above mentioned method do not belong to self-restrictedly growing in-situ, and needs assistance from a transferring process of graphene. Thus, the process as mentioned above has a poor process stability, and it is difficult to control the process deviation and it can't be applied for large scale integration.

### SUMMARY

An objective of the present disclosure is to provide a method for manufacturing a two-dimensional material structure and a resultant two-dimensional material device, especially for a two-dimensional nanometer device.

According to one aspect of the present disclosure, there is provided a method for manufacturing a two-dimensional material structure, comprising steps of: forming a sacrificial FIN structure on a substrate; covering the sacrificial FIN structure with a dielectric; releasing the sacrificial FIN structure; forming a carrier FIN structure at a position for releasing the sacrificial FIN; and self-restrictedly growing two-dimensional material structure.

Preferably, the two-dimensional material may be graphene, and the two-dimensional material may also be other suitable two-dimensional material, such as the two-dimensional material of transitional metal sulfide (TMD) or black phosphorus and so on.

Preferably, the step of releasing the sacrificial FIN structure comprises: etching back a layer of the dielectric until the sacrificial FIN structure is exposed; and etching back the sacrificial FIN structure by taking the layer of dielectric as a mask.

Preferably, after the step of forming a carrier FIN structure at a position for releasing the sacrificial FIN, the method may further comprise etching the layer of dielectric to expose a top end, sides or both of them of the carrier FIN structure.

Preferably, the method further comprises a step of: self-restrictedly growing nanometer structure of the two-dimensional material on the exposed carrier FIN structure by taking the carrier FIN structure as a substrate.

Preferably, after the step of self-restrictedly growing nanometer structure of the two-dimensional material by taking the carrier FIN structure as a substrate, the method may further comprise releasing the carrier FIN structure to form a suspended channel of the two-dimensional material.

Preferably, the two-dimensional material structure is a nanometer structure of the two-dimensional material. The nanometer structure of the two-dimensional material may be a two-dimensional material nanometer belt and so on.

Preferably, a material for the carrier FIN structure is lattice matched with that of the two-dimensional material.

According to another aspect of the present disclosure, there is provided a two-dimensional material device, which is manufactured by the method for manufacturing a two-dimensional material structure as mentioned above.

The present disclosure provides a method capable of controlling topography of the grown two-dimensional material by implementing a FIN structure of a carrier material through the high precision process for the substrate material. Furthermore, an in-situ self-restrictedly growing of the nanometer structure of the two-dimensional material is implemented, which may precisely control the size and equality of the nanometer structure of the two-dimensional material at a lower cost and may implement a large-scale production and an integration of high density.

### BRIEF DESCRIPTION OF THE DRAWINGS

The embodiments of the present disclosure will be illustrated in detail with respect to accompany figures, in which:

FIG. 1a shows a schematic view of forming a sacrificial FIN structure on the substrate;

FIG. 1b shows a schematic view of filling a dielectric layer on the sacrificial FIN structure;

FIG. 1c shows a schematic view of etching back the dielectric layer to expose the sacrificial FIN structure;

FIG. 1d shows a schematic view of a resultant structure after releasing the sacrificial FIN structure;

FIG. 1e shows a schematic view of epitaxial growing a carrier FIN structure at a position left after releasing the sacrificial FIN structure;

FIG. 1f shows a schematic view of self-restrictedly growing nanometer structure of the two-dimensional material on top of the carrier FIN structure by taking the carrier FIN structure as a substrate;

FIG. 2a shows a schematic view of another carrier FIN structure;

FIG. 2b shows a schematic view of self-restrictedly growing nanometer structure of the two-dimensional material on top and side surfaces of the carrier FIN structure by taking the carrier FIN structure as a substrate;

FIG. 2c shows a schematic view of self-restrictedly growing nanometer structure of the two-dimensional material only on side surfaces of the carrier FIN structure by taking the carrier FIN structure as a substrate; and

FIG. 3 shows a flowchart of a method for manufacturing a nanometer structure of the two-dimensional material according to an embodiment of the present disclosure.

### DETAILED DESCRIPTION

The embodiments of the present disclosure will be illustrated in detail, the examples of which would be described in the figures. In the figures, identical reference signs represent identical elements. The following embodiments of the present disclosure will be explained by referring to the figures.

For the technical issue of manufacturing a nanometer structure of the two-dimensional material, the present disclosure provides a method for manufacturing a two-dimensional material structure with a controllable topography and size by utilizing a FIN structure to implement a self-restrictedly growing of the nanometer structure of the two-dimensional material. Such a method has a high precision, lower edge roughness and in a scale of nanometer, and has characteristics of high yields and low process deviation, so it is suitable for a large-scale production.

The method for manufacturing two-dimensional material according to embodiments of the present disclosure will be particularly illustrated by taking a two-dimensional material of graphene as an example. It should be notated that the two-dimensional material may be graphene, and the two-dimensional material may also be other suitable two-dimensional material, such as transition metal sulphide (TMD), black phosphorus or the like.

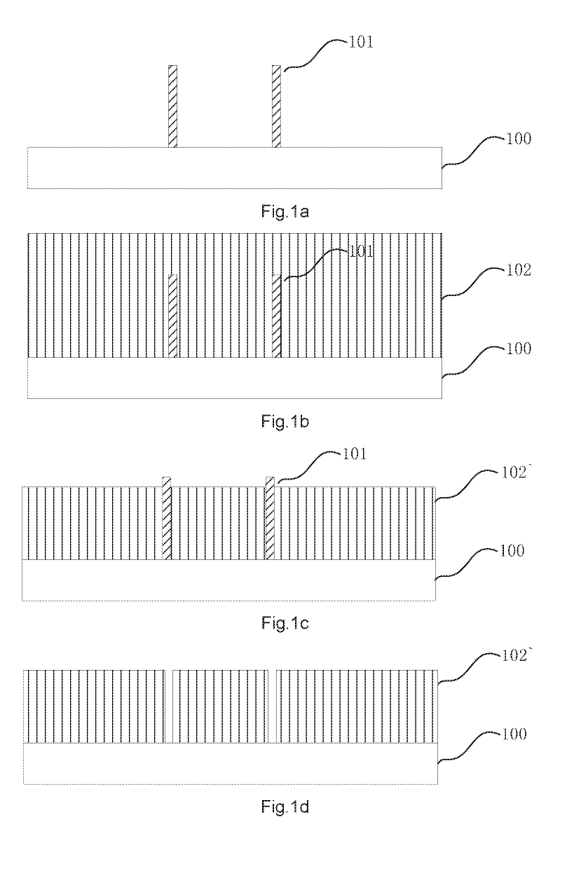

FIG. 1a shows a schematic view of forming a sacrificial FIN structure on the substrate. As shown in FIG. 1a, a sacrificial Fin structure of a substrate material A is formed on a prepared substrate 100.

The substrate material A maybe Si, SiC and so on. Since the substrate material A is a familiar material in the semiconductor field, the sacrificial FIN structure 101 manufactured by the semiconductor material has a mature process, a high precision and a low cost.

As shown in FIG. 1b, a dielectric layer 102 is filled to cover the resultant sacrificial FIN structure 101. FIG. 1b shows a schematic view of filling a dielectric layer on the sacrificial FIN structure. Filing the dielectric layer 102 may be implemented by deposition or ALD, and may comprise but is not limited to PECVD, LPCVD, ALD and so on. In particular, the material for the dielectric may be but not limited to dielectric materials such as silicon oxide, silicon nitride, silicon oxynitride, aluminum oxide, hafnium oxide, and the like.

Then, the filled dielectric layer 102 is etched back until the top end of the sacrificial FIN structure 101 is exposed, as shown in FIG. 1c. FIG. 1c shows a schematic view of etching back the dielectric layer to expose the sacrificial FIN structure. The extent of etching back depends on sizes of the carrier material for the two-dimensional material which is subsequently formed on the carrier FIN structure. As shown in FIG. 1c, the remaining dielectric layer after being etched back is represented as 102′. In particular, the step of etching back may be implemented by dry etching or wet etching. In order to better control etched pattern, it is preferable to utilize the dry etching. A typical method of dry etching utilizes plasma generated by argon to bombard and thin the dielectric layer. Other alternative means for the dry etching is ICP (Inductively Coupled Plasma) etching or RIE (Reactive Ion Etching). FIG. 1d shows a schematic view of a resultant structure after releasing the sacrificial FIN structure. As shown in FIG. 1d, the sacrificial FIN structure 101 is etched off by utilizing etchant for the substrate material so as to release the sacrificial FIN structure 101 and to leave a trench defined by the pattern of the sacrificial FIN structure 101.

FIG. 1e shows a schematic view of epitaxial growing a carrier FIN structure at a position left after releasing the sacrificial FIN structure. As shown in FIG. 1e, a FIN structure 103 of a carrier material B is epitaxial grown at a position left after releasing the sacrificial FIN structure. The carrier material B is a material on which the nanometer structure of the two-dimensional material may be attached and continues to be grown. In particular, the carrier material B may be a semiconductor material such as germanium, selenium and so on. The reason for selecting the material B as the carrier is that the lattice matching of the carrier material B facilitates to directly manufacture a two-dimensional material with a high quality on it. Secondly, the carrier material B is expensive with respect to the material of silicon, so if a conventional etching process is directly utilized to manufacture the FIN structure of the carrier material B, it will lead to a great waste of the carrier material B so as to increase cost of production. The embodiment of the present disclosure precisely defines the FIN structure by utilizing a cheap silicon material, releases the FIN structure and filling with the carrier material B so as to form the FIN structure of the carrier material, which greatly saves consumption of the carrier material B. Since the process of the substrate material A is mature and is compatible with the existing semiconductor process, the process difficulty and cost is decreased.

As mentioned above, the embodiment of the present disclosure actually utilizes technical means of photolithography, etching and filling and so on for the substrate material A to get the FIN structure of the carrier material B. After the FIN structure of the carrier material is obtained, a nanometer structure of the two-dimensional material may be self-restrictedly grown by taking the FIN structure of the carrier material B as a substrate. For example, the shape of the FIN structure may be controlled according to a desired nanometer structure of the two-dimensional material as to control a pattern of the nanometer structure of the two-dimensional material.

The two-dimensional material structure epitaxial grown on the above mentioned carrier material B will be illustrated in conjunction with accompany figures. FIG. 1f shows a schematic view of self-restrictedly growing nanometer structure of the two-dimensional material on top of the carrier FIN structure by taking the carrier FIN structure as a substrate. As shown in FIG. 1f, it shows a self-restrictedly grown nanometer structure 104 of the two-dimensional material by taking the carrier FIN structure 103 of the carrier material B as a substrate. As mentioned above, a material for the two-dimensional material nanometer structure may be grapheme. That is to say, by taking the FIN structure 103 of the carrier material, a two-dimensional material nanometer structure 104 of graphene is self-restrictedly grown on the carrier FIN structure 103. Since a sacrificial FIN structure of the substrate material with different shapes and sizes may be easily formed by photolithography and etching of the substrate material A, the shape and size of the carrier FIN structure may be controlled, in turn the shape and size of the self-restrictedly grown two-dimensional material nanometer structure. Here, the self-restrictedly growing may be considered as self-organized growing, which represents that the material for the two-dimensional nanometer structure may only be grown by taking the carrier material as the substrate, and the two-dimensional material nanometer structure can't be grown at a position without carrier material B.

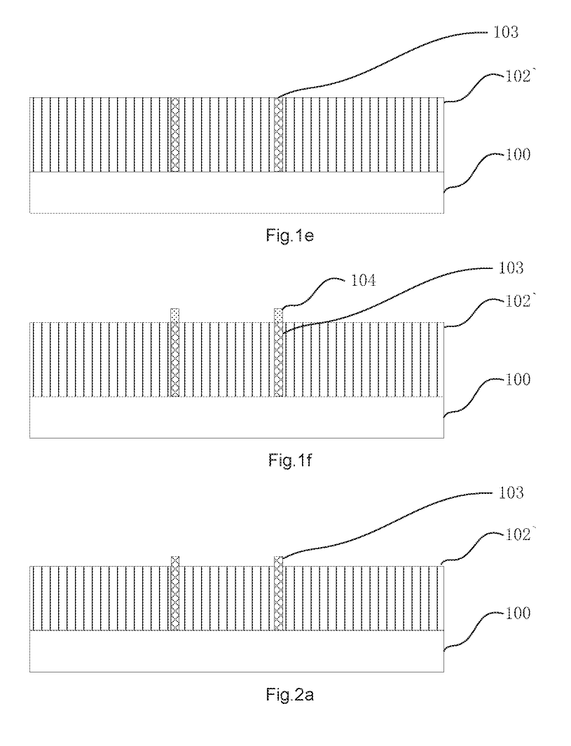

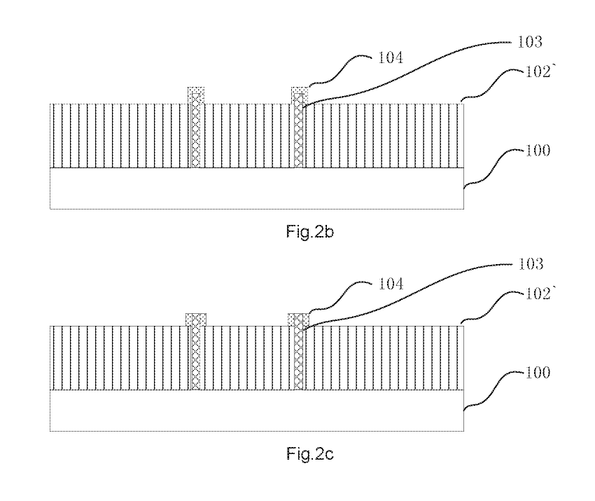

FIG. 2a shows a schematic view of another carrier FIN structure. As shown in FIG. 2a, after the process as shown in FIG. 1d, a FIN structure 103 of the carrier material B is epitaxial grown at a position left after releasing the sacrificial FIN structure to get the FIN structure of 103 as shown in FIG. 1e. Then, the dielectric layer continues to be etched until the FIN structure 103 of the carrier material B is exposed. The remaining dielectric layer is represented as 102′. The degree of exposing the FIN structure 103 (i.e. the etching degree of the dielectric layer 102) depends on requirement of forming the FIN structure of the two-dimensional material.

In the following, two overlaying layers with different topography may be grown on the FIN structure 103 by taking the FIN structure 103 of the carrier material B as the substrate and controlling crystal orientation of the carrier material B. FIG. 2b shows a schematic view of self-restrictedly growing nanometer structure of the two-dimensional material on top and side surfaces of the carrier FIN structure by taking the carrier FIN structure as a substrate. In particular, as shown in FIG. 2b, a two-dimensional material 104 which packaging the carrier FIN structure 103 is self-restrictedly grown by taking the FIN structure 103 of the carrier material B as the substrate. FIG. 2c shows a schematic view of self-restrictedly growing nanometer structure of the two-dimensional material only on side surfaces of the carrier FIN structure by taking the carrier FIN structure as a substrate. As shown in FIG. 2c, the two-dimensional material layer 104 is only self-restrictedly grown on side surfaces of the carrier FIN structure 103 by taking the carrier FIN structure 103 of the carrier material B as a substrate. In particular, by selecting the crystal orientation of the FIN structure, it may selectively control to grow the two-dimensional material layer only on side surfaces of the FIN structure so as to get the two-dimensional material layer 104 with different topography. The two-dimensional material layer 104 with different topography may be utilized to manufacture a device.

The two-dimensional material layer 104 as mentioned above may be directly utilized to manufacture a device.

In addition, after the two-dimensional material layer 104 is formed, the FIN structure 103 of the carrier material B may be released to form a suspended channel of the two-dimensional material, and then a semiconductor device including the suspended channel of the two-dimensional material may be further manufactured.

Furthermore, a dielectric layer may be formed on the two-dimensional layer 104, a metal layer is deposited and the carrier FIN structure 103 of the carrier material B is released to form a suspended channel of the two-dimensional material. Then, the semiconductor device including the suspended channel of the two-dimensional material may be further manufactured.

The carrier material for the FIN structure is not limited to some specific material, and it may be any semiconductor materials which may epitaxial grow the two-dimensional material nanometer structure.

The dielectric layer may employ any dielectric and is not limited to silicon oxide, silicon nitride and so on.

The means for growing the two-dimensional material may be any means such as normal pressure, high-pressure, low-pressure, plasma enhancement and so on.

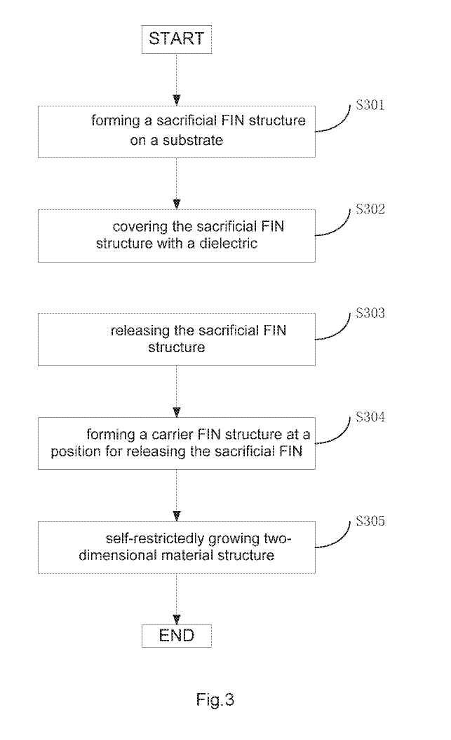

FIG. 3 shows a flowchart of a method for manufacturing a nanometer structure of the two-dimensional material according to an embodiment of the present disclosure. As shown in FIG. 3, the method comprises steps of: forming a sacrificial FIN structure on a substrate (S301); covering the sacrificial FIN structure with a dielectric (S302); releasing the sacrificial FIN structure (S303); forming a carrier FIN structure at a position for releasing the sacrificial FIN (S304); and self-restrictedly growing two-dimensional material structure by taking the carrier FIN structure as a substrate (S305). By utilizing the sacrificial FIN structure to implement self-restrictedly growing of the nanometer structure of the two-dimensional material, the present disclosure has a high precision, lower edge roughness, high yields and low process deviation, so it is suitable for a large-scale production.

The two-dimensional material may be graphene, and the two-dimensional material may also be other suitable two-dimensional material, such as the two-dimensional material of transitional metal sulfide (TMD) or black phosphorus and so on.

The step of releasing the sacrificial FIN structure comprises: etching back a layer of the dielectric until the sacrificial FIN structure is exposed; and etching back the sacrificial FIN structure by taking the layer of dielectric as a mask.

After the step of forming a carrier FIN structure at a position for releasing the sacrificial FIN, the method may further comprise etching the layer of dielectric to expose a top end, sides or both of them of the carrier FIN structure.

The method further comprises a step of: self-restrictedly growing nanometer structure of the two-dimensional material on the exposed carrier FIN structure by taking the carrier FIN structure as a substrate.

After the step of self-restrictedly growing nanometer structure of the two-dimensional material by taking the carrier FIN structure as a substrate, the method may further comprise releasing the carrier FIN structure to form a suspended channel of the two-dimensional material.

According to another aspect of the present disclosure, there is provided a two-dimensional material device, which is manufactured by the method for manufacturing a two-dimensional material structure as mentioned above.

The present disclosure provides a method capable of controlling topography of the grown two-dimensional material by implementing a FIN structure of a carrier material through the high precision process for the substrate material. Furthermore, an in-situ self-restrictedly growing of the nanometer structure of the two-dimensional material is implemented, which may precisely control the size and equality of the nanometer structure of the two-dimensional material at a lower cost and may implement a large-scale production and an integration of high density.

For the technical issue of manufacturing a nanometer structure of the two-dimensional material, the present disclosure provides a method for manufacturing a two-dimensional material structure with a controllable topography and size by utilizing a FIN structure to implement a self-restrictedly growing of the nanometer structure of the two-dimensional material. Such a method has a high precision, lower edge roughness and in a scale of nanometer, and has characteristics of high yields and low process deviation, so it is suitable for a large-scale production.

The method of the present disclosure has the following advantages. The method may implement a self-restrictedly growing of the two-dimensional material nanometer structure by effectively control topography and size of the two-dimensional material by a mature and precise process in the field of manufacturing semiconductor device to get a lower edge roughness. The method avoids a subsequent process of transferring, etching or the like for the two-dimensional material, which may effectively improve cleanness of the surface of the two-dimensional material to decrease surface states, and may implement an in-situ manufacturing of the two-dimensional material device. The method is compatible with that of the existing large scale integrated circuit and is suitable for large scale industrial production. The method according to the present disclosure has a higher precision and a lower process deviation.

Although the present invention is particularly illustrate and described with respect to typical embodiments of the present disclosure, it should be understood for those skilled in the art that there may be various modifications in form and details for the embodiments without departing from the spirit and scope of the present invention defined by the apposed claims.

I/We claim:

1. A method for manufacturing a two-dimensional material structure, comprising steps of:
forming a sacrificial FIN structure on a substrate;
covering the sacrificial FIN structure with a dielectric;
releasing the sacrificial FIN structure;
forming a carrier FIN structure at a position for releasing the sacrificial FIN; and
self-restrictedly growing two-dimensional material structure by taking the carrier FIN structure as a substrate.

2. The method according to claim 1, wherein the two-dimensional material is graphene, transitional metal sulfide TMD or black phosphorus.

3. The method according to claim 1, wherein the step of releasing the sacrificial FIN structure comprises:
etching back a layer of the dielectric until the sacrificial FIN structure is exposed; and
etching back the sacrificial FIN structure by taking the layer of dielectric as a mask.

4. The method according to claim 3, wherein the etching back is implemented by dry etching or wet etching.

5. The method according to claim 1, after the step of forming a carrier FIN structure at a position for releasing the sacrificial FIN, the method further comprising etching the layer of dielectric to expose a top end, sides or both top end and sides of the carrier FIN structure.

6. The method according to claim 5, wherein the method further comprises a step of: self-restrictedly growing nanometer structure of the two-dimensional material on the exposed carrier FIN structure by taking the carrier FIN structure as a substrate.

7. The method according to claim 1, further comprising: after the step of self-restrictedly growing nanometer structure of the two-dimensional material by taking the carrier FIN structure as a substrate, releasing the carrier FIN structure to form a suspended channel of the two-dimensional material.

8. The method according to claim 1, wherein the two-dimensional material structure is a nanometer structure of the two-dimensional material.

9. The method according to claim 1, wherein a material for the carrier FIN structure is lattice matched with that of the two-dimensional material.

10. A two-dimensional material device including a two-dimensional material structure which is manufactured by the method according to any claim 1.
